(19) United States
(12) Patent Application Publication
(10) Pub. No.: US 2019/0064401 A1
(43) Pub. Date: Feb. 28, 2019

(54) REFLECTIVE EXPOSURE APPARATUS

(71) Applicant: FOXSEMICON INTEGRATED TECHNOLOGY, INC., Miao-Li Hsien (TW)

(72) Inventors: YI-CHUN CHIU, New Taipei (TW); CHUN-KAI HUANG, New Taipei (TW); CHIH-CHENG LU, Miaoli Hsien (TW); CHUN-CHUNG CHEN, Miaoli Hsien (TW); CHEN-TSU FU, New Taipei (TW); SHENG-FU TSAI, New Taipei (TW)

(21) Appl. No.: 15/853,359

(22) Filed: Dec. 22, 2017

(30) Foreign Application Priority Data
Aug. 25, 2017 (TW) 106128972

(51) Int. Cl. G02B 5/08; G03F 7/20

(52) U.S. Cl. CPC G02B 5/08; G03F 7/2008

(57) ABSTRACT

A reflective exposure apparatus includes a platform, an illuminating system, a photomask, a chip, and a reflecting convex mirror. The photomask is formed on the platform and faces the illuminating system. The chip is formed on the platform. The illuminating system and the reflecting curved mirror are formed on opposite sides of the platform. The platform can be moved relative to the illuminating system and the reflecting curved mirror.

### FIELD

The subject matter generally relates to an exposure apparatus, and more particularly, to a reflective exposure apparatus.

### BACKGROUND

A conventional exposure machine generally includes a light source, a photomask, a refracting lens, and a chip. The refracting lens is used to collect and diffuse light from the light source to focus on the chip. However, a large projection lens with a low aberration is costly. For a small cheaper projection lens, the small cheaper projection lens needs to focus locally repeatedly. Thus, a high accuracy requirement for the platform is needed.

### BRIEF DESCRIPTION OF THE DRAWINGS

Implementations of the present disclosure will now be described, by way of example only, with reference to the attached figures.

FIG. 1 is a diagrammatic view of an exemplary embodiment of a reflective exposure apparatus of the present disclosure.

FIG. 2 is a diagrammatic view of an illuminating system of the reflective exposure apparatus of FIG. 1.

FIG. 3 is a diagrammatic view of another exemplary embodiment of an illuminating system of the reflective exposure apparatus of FIG. 1.

### DETAILED DESCRIPTION OF EMBODIMENTS

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale, and the proportions of certain parts may be exaggerated to illustrate details and features of the present disclosure better.

The disclosure is illustrated by way of example and not by way of limitation in the figures of the accompanying drawings, in which like references indicate similar elements. It should be noted that references to “an” or “one” embodiment in this disclosure are not necessarily to the same embodiment, and such references mean “at least one.”

The term “comprising” when utilized, means “including, but not necessarily limited to”; it specifically indicates open-ended inclusion or membership in the so-described combination, group, series, and the like.

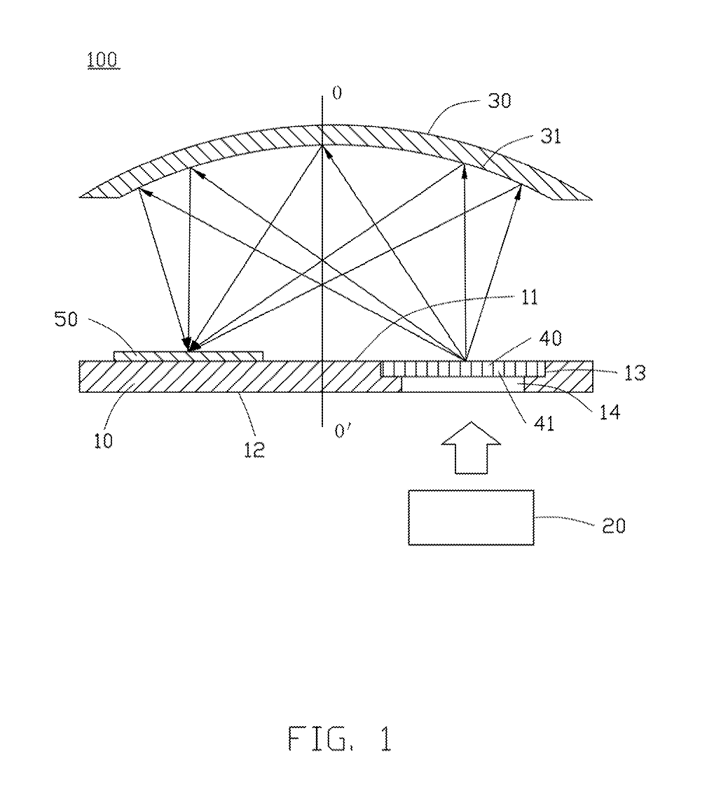

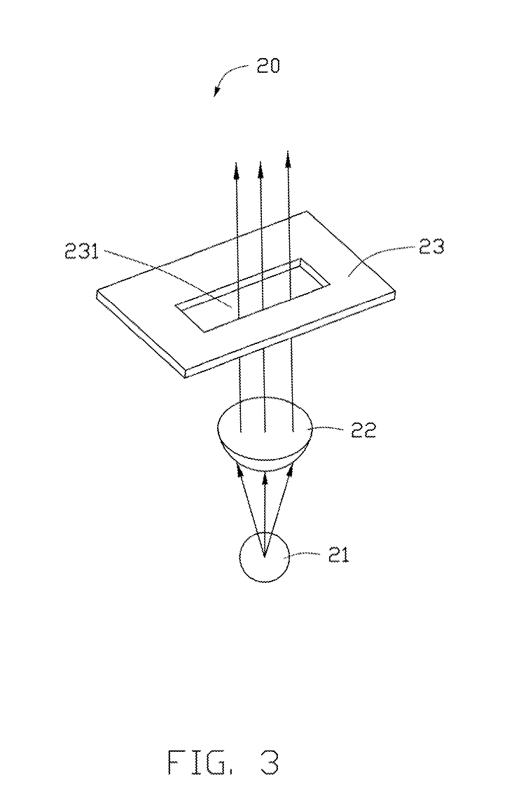

FIGS. 1 to 3 illustrate an exemplary embodiment of a reflective exposure apparatus 100. The reflective exposure apparatus 100 includes a platform 10, an illuminating system 20, a reflecting convex mirror 30, a photomask 40, and a chip 50. The illuminating system 20 and the reflecting curved mirror 30 are formed on two opposite sides of the platform 10. The platform 10 can be moved relative to the illuminating system 20 and the reflecting curved mirror 30. The photomask 40 and the chip 50 are formed on the platform 10 and spaced from each other.

The platform 10 includes a first surface 11 and a second surface 12 facing away from the first surface 11. The photomask 40 and the chip 50 are formed on the first surface 11.

The platform 10 further includes a receiving groove 13 and a light guide groove 14 connected with the receiving groove 13. The receiving groove 13 is used to receive the photomask 14. The light guide groove 14 is used to guide parallel light beams 25 emitted from the illumination system 20 into the photomask 40. The receiving groove 13 and the light guide groove 14 cooperatively run through the platform 10.

In at least one exemplary embodiment, the receiving groove 13 and the light guide groove 14 have a same central axis (e.g., concentric).

In at least one exemplary embodiment, the receiving groove 13 has a larger width than the light guide groove 14.

The illuminating system 20 is formed on one side of the platform 10 and faces the second surface 12.

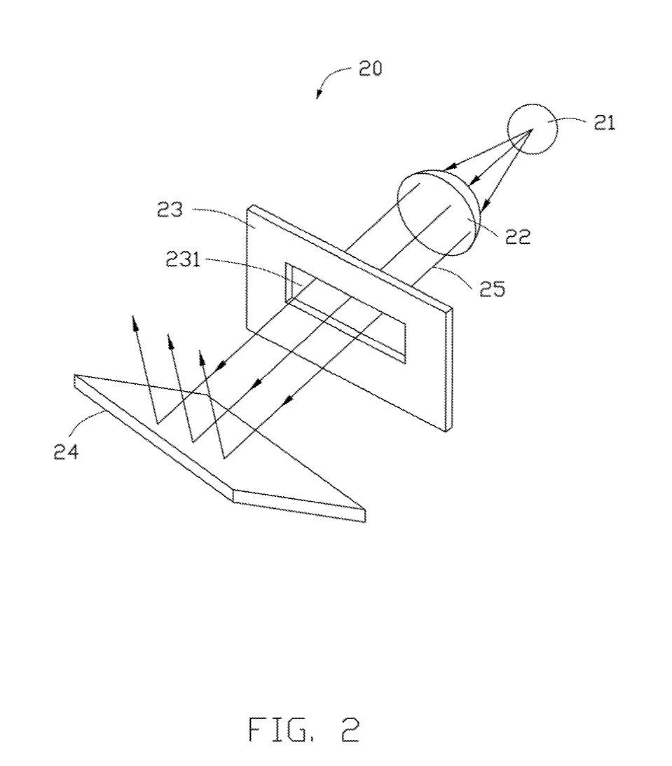

In at least one exemplary embodiment, as shown in FIG. 2, the illuminating system 20 includes a light source 21, a condenser lens 22, and a slot plate 23. The condenser lens 22 is formed between the light source 21 and the slot plate 23. The slot plate 23 faces the condenser lens 22. The slot plate 23 includes a slot 231 in the middle of the narrow slot 23. The slot plate 23 is used to block a portion of the parallel light beam 25 that is not used to illuminate the photomask 40, thereby forming an exposure area having a predetermined size. Light emitted from the light source 21 travels to the condenser lens 22, which converts the light to be parallel light beams 25. The parallel light beams 25 then travel to the photomask 40 through the light guide groove 14.

In other exemplary embodiment, the illuminating system 20 further includes a reflector 24. The slot plate 23 is formed between the condenser lens 22 and the reflector 24. The condenser lens 22 is formed between the light source 21 and the slot plate 23. The reflector 24 faces the photomask 40 and is inclined to the platform 10. The reflector 24 changes the direction of the parallel light beams 25 to be perpendicular to the photomask 40, when the parallel light beam 25 is not perpendicular to the photomask 40.

In other exemplary embodiment, the slot plate 23 can be omitted.

The reflecting convex mirror 30 includes a reflecting surface 31. The reflecting surface 31 faces the photomask 40 and the chip 50. The reflecting surface 31 is a curved surface.

The reflecting surface 31 has a light axis OO′. The light axis OO′ is perpendicular to the first surface 11 of the platform 10.

The photomask 40 is received in the receiving groove 13. The photomask 40 includes photomask patterns 41.

In at least one exemplary embodiment, a surface of the photomask 40 facing away from the light guide groove 14 is coplanar with the first surface 11.

The chip 50 is formed on the first surface 11 of the platform 10. The chip 50 is photoreceptive, when the light reflected by the reflecting convex mirror 30 travels to the chip 50, the photomask patterns 41 appear on the chip 50.

When in use, the platform 10 is moved to make the illumination system 20 face the photomask 40 and the parallel light beams 25 emitted from the illumination system 20 cover a portion of the photomask patterns 41 of the photomask 40. The parallel light beams 25 travel through the photomask 40 to the reflecting surface 31 of the reflecting curved mirror 30, and are reflected by the reflecting surface 31 onto the chip 50. Thus, the photomask patterns 41 of the photomask 40 can be completely transferred to the chip 50 by repeating the above operations.

With the above configuration, 1) the photomask 40 does not need to be locally exposed repeatedly, but only needs to be statically aligned firstly, and the platform moved with a constant speed. 2) Since the reflective exposure apparatus 100 does not need to be aligned for each lens and only needs one static alignment, a high accuracy requirement for the platform 10 of the reflective exposure apparatus 100 is not essential. 3) the photomask 40 and the chip 50 are positioned on the same surface of the platform 10 and are spaced from each other, thereby scratching between the photomask 40 and the chip 50 can be avoided. 4) Size of the reflecting convex mirror 30 can be varied, and 5), the reflecting convex mirror 30 can reduce chromatic aberration in the reflective exposure apparatus 100 and give a better resolution.

The embodiments shown and described above are only examples. Many details are often found in the art such as the other features of the reflective exposure apparatus having the same. Therefore, many such details are neither shown nor described. Even though numerous characteristics and advantages of the present disclosure have been positioned forth in the foregoing description, together with details of the structure and function of the present disclosure, the disclosure is illustrative only, and changes can be made in the detail, including in matters of shape, size, and arrangement of the parts within the principles of the present disclosure, up to and including the full extent established by the broad general meaning of the terms used in the claims. It will therefore be appreciated that the embodiments described above can be modified within the scope of the claims.

What is claimed is:

1. A reflective exposure apparatus, comprising:
a platform,
an illuminating system,
a photomask, wherein the photomask is formed on the platform and faces the illuminating system;
a chip, wherein the chip is formed on the platform; and
a reflecting convex mirror, wherein the illuminating system and the reflecting curved mirror are formed on two opposite sides of the platform, the platform is configured to move relative to the illuminating system and the reflecting curved mirror.

2. The reflective exposure apparatus of claim 1, wherein the platform comprises a first surface and a second surface facing away from the first surface; the chip is formed on the first surface.

3. The reflective exposure apparatus of claim 2, wherein the reflecting convex mirror faces with on the first surface, the illuminating system faces with the second surface.

4. The reflective exposure apparatus of claim 2, wherein the platform further comprises a receiving groove and a light guide groove connected to the receiving groove, the photomask is received in the receiving groove, the illuminating system faces the light guide groove.

5. The reflective exposure apparatus of claim 4, wherein the receiving groove and the light guide groove have a same central axis.

6. The reflective exposure apparatus of claim 4, wherein the receiving groove has a larger width than that of the light guide groove.

7. The reflective exposure apparatus of claim 1, wherein the reflecting convex mirror comprises a reflecting surface, the reflecting surface faces the photomask and the chip.

8. The reflective exposure apparatus of claim 7, wherein the reflecting surface is a curved surface.

9. The reflective exposure apparatus of claim 7, wherein the reflecting surface has a light axis, the light axis is perpendicular to the first surface of the platform.

10. The reflective exposure apparatus of claim 4, wherein the illuminating system comprises a light source and a condenser lens, the condenser lens is formed between the light source and the photomask, the condenser lens converts light emitted from the light source to be parallel light beams, thereby allowing the parallel light beams to travel to the photomask through the light guide groove.

11. The reflective exposure apparatus of claim 10, wherein the illuminating system further comprises a slot plate, the condenser lens is formed between the light source and the slot plate.

12. The reflective exposure apparatus of claim 1, wherein the illuminating system further comprises a light source, a condenser lens, and a reflector, and wherein the condenser lens is formed between the light source and the reflector.

13. The reflective exposure apparatus of claim 12, wherein the reflector faces the photomask and is inclined to the platform, the reflector converts light emitted from the light source to the condenser lens, which converts the light to be parallel light beams, the parallel light beams then travel to the reflector.

14. The reflective exposure apparatus of claim 13, wherein the illuminating system further comprises a slot plate, the slot plate is formed between the condenser lens and the reflector.
